(19) United States
(12) Patent Application Publication
(10) Pub. No.: US 2019/0109155 A1
(43) Pub. Date: Apr. 11, 2019

(54) ARRAY SUBSTRATE, METHOD OF PRODUCING THE SAME, AND DISPLAY PANEL

(71) Applicant: SHARP KABUSHIKI KAISHA, Sakai City (JP)

(72) Inventors: SETSUJI NISHIMIYA, Sakai City (JP); TOHRU DAITOH, Sakai City (JP); HAJIME IMAI, Sakai City (JP); MASAHIKO SUZUKI, Sakai City (JP); TETSUO KIKUCHI, Sakai City (JP); TERUYUKI UEDA, Sakai City (JP); KENGO HARA, Sakai City (JP)

(21) Appl. No.: 16/157,090

(22) Filed: Oct. 10, 2018

(30) Foreign Application Priority Data
Oct. 11, 2017 (JP) 2017-197433

(51) Int. Cl. H01L 27/12; H01L 23/532; H01L 21/768

(52) U.S. Cl. CPC H01L 27/124; H01L 21/7685; H01L 23/53238

(57) ABSTRACT

An array substrate including a spin-on glass layer formed of spin-on glass material, a first line disposed on a lower side with respect to the spin-on glass layer, the first line including a copper containing layer formed of copper or a copper alloy and a metal upper layer formed of one selected from a group consisting of titanium, an aluminum alloy, a copper alloy, a tungsten alloy, and a tantalum alloy, and the metal upper layer disposed on the copper containing layer and disposed between the copper containing layer and the spin-on glass layer, and a second line disposed on an upper side with respect to the spin-on glass layer and overlapping the first line in a plan view.

### CROSS REFERENCE TO RELATED APPLICATION

This application claims priority from Japanese Patent Application No. 2017-197433 filed on Oct. 11, 2017. The entire contents of the priority application are incorporated herein by reference.

### TECHNICAL FIELD

The technology described herein relates to an array substrate, a method of producing the array substrate, and a display panel.

### BACKGROUND

A display panel including an array substrate has been known as a display panel displaying images thereon. On the array substrate, gate lines (scanning lines) and source lines (signal lines, data lines) are disposed to cross each other in an array. The gate lines and the source lines define pixel regions and a pixel electrode is arranged in each of the pixel regions. The pixel electrode is connected to the source line through a thin film transistor (TFT), which is used as a switching component. The TFTs are driven based on various kinds of signals supplied to the gate lines and the source lines and supply of the potential to the pixel electrodes is controlled by the driving of the TFTs. Copper having smaller electric resistance is preferably used for metal film material of the gate lines and the source lines. There has been proposed a copper alloy film for a display device in Japanese Unexamined Patent Application Publication No. 2012-27159. Such a copper alloy film has a multilayer structure including a first layer including different type of metal such as titanium having high adhesion to a gate insulation film and a second layer mainly including copper.

While the display panel has been demanded to have enhanced resolution, the wiring on the array substrate has been demanded to be minute to increase the aperture ratio of the pixels. However, if a line width is simply reduced, the electric resistance is increased and signal delay may be caused. For example, if the line film thickness is increased while reducing the line width, the electric resistance is less likely to be increased. However, the surfaces of the lines are uneven and level difference between the lines is large, and disconnection of the wiring is likely to be caused.

### SUMMARY

The technology described herein was made in view of the above circumstances and an object is to produce an array substrate suitable for enhanced resolution with a simple process.

An array substrate according to the present technology includes a spin-on glass layer formed of spin-on glass material, a first line disposed on a lower side with respect to the spin-on glass layer, the first line including a copper containing layer formed of copper or a copper alloy and a metal upper layer formed of one selected from a group consisting of titanium, an aluminum alloy, a copper alloy, a tungsten alloy, and a tantalum alloy, and the metal upper layer disposed on the copper containing layer and disposed between the copper containing layer and the spin-on glass layer, and a second line disposed on an upper side with respect to the spin-on glass layer and overlapping the first line in a plan view.

According to the above configuration including a line of a double-layer structure, an appropriate line thickness can be kept and a line width can be reduced without increasing the electric resistance. Accordingly, an aperture ratio of pixels can be increased and resolution of displayed images can be enhanced. In a display panel having a gate driver monolithic (GMD) circuit including a gate driver circuit in a frame area, a cross capacity is reduced by forming the gate line in the double-layer structure.

According to the above configuration, the SOG layer formed of SOG material is disposed between the lines of the double-layer structure as an insulation layer. After forming the SOG layer, an annealing treatment may be performed at a high temperature (for example, 350° C. or higher) in the process of producing a display panel. The SOG layer is superior in the heat-resistance property. Therefore, the insulation layer is less likely to be deteriorated or modified even if the SOG layer is exposed to the high temperature by the high temperature annealing treatment. Accordingly, a highly reliable display panel can be obtained with using the array substrate. Considering the heat resistance property, the SOG material that is thermally cured at the end is preferable. A film can be formed and a pattern can be formed on photosensitive SOG material with the photolithography method. Therefore, the number of processes in producing the array substrate is less likely to be increased.

In the array substrate including the line of the double-layer structure, if the first line, which is included on the lower side with respect to the SOG layer, is formed from a known multilayer metal film including two layer structure, copper included in the exposed upper layer is contacted with the SOG layer. In the array substrate having such a configuration, copper is oxidized by the heating process performed for curing the SOG layer. It is necessary to form a metal capping layer formed of silicon nitride to cover the first line after forming the first line. This increases the number of processes in producing an array substrate.

According to the above configuration, the metal upper layer is disposed between the copper containing layer of the first line and the SOG layer that may oxidize the copper included in the copper containing layer. Therefore, oxidization of the copper included in the copper containing layer is restricted without forming the metal capping layer and the electric resistivity of the line can be kept low.

According to the above configuration, the metal upper layer is formed of one selected from a metal group consisting of titanium, an aluminum alloy, a copper alloy, a tungsten alloy, and a tantalum alloy. With using such a metal for the metal upper layer, a dense layer can be formed on the upper surface of the copper containing layer. Furthermore, with using such a metal, the copper containing layer and the metal upper layer are formed with a simple process of disposing sequentially the metal containing copper and the metal upper layer with sputtering.

An array substrate that is suitable for high resolution and restricts signal delay and has high reliability can be produced with a simple process.

An array substrate of the present technology is produced with a flowing method. The method includes a multilayer metal film forming process of forming a multilayer metal film including a copper containing layer formed of copper or a copper alloy and a metal upper layer formed of one selected from a group consisting of titanium, an aluminum alloy, a copper alloy, a tungsten alloy, and a tantalum alloy, and the metal upper layer disposed on the copper containing layer, a first line pattern forming process of forming a first line pattern on the multilayer metal film with etching, a spin-on glass layer forming process of forming a spin-on glass layer formed of spin-on glass material on the first line pattern, and a second line pattern forming process of forming a second line pattern so as to overlap the first line pattern in a plan view and be disposed on an upper side with respect to the spin-on glass layer.

According to the above method, an array substrate including the line of a double-layer structure and keeping an appropriate line thickness and reducing the line width without increasing the electric resistance can be obtained. The SOG layer having high heat resistance property is disposed between the lines included in the double-layer structure as the insulation layer and is less likely to be deteriorated or deformed by the high temperature treatment performed in the process of producing a display panel. Further, the metal upper layer is disposed between the copper containing layer of the first line and the SOG layer that may oxidize copper included in the layer. The multilayer metal film of the first line is formed by disposing copper or a copper alloy and metal upper layer forming metal sequentially with sputtering. According to the above configuration, the first line pattern is formed with etching after the multilayer metal film including the metal upper layer in a most upper layer is formed. Accordingly, the contact area in which the copper containing layer and the SOG layer are directly in contact with each other is reduced and oxidization of copper in thermosetting of the SOG layer is less likely to be caused. Therefore, a metal capping layer is not required to be formed. With the configuration including the SOG layer formed of photosensitive SOG material, the pattern can be formed with the photolithography method. Therefore, the number of processes in producing the array substrate is less likely to be increased. As a result, oxidization of the copper containing layer included in the first line is less likely to be caused and the highly reliable array substrate can be obtained with a simple process.

According to the technology described herein, an array substrate that is suitable for enhanced resolution and has highly reliability is obtained with a simple producing process. A display panel that is highly reliable and displays an image with enhanced resolution can be obtained by applying the present technology to a liquid crystal panel, a plasma display panel, an organic EL panel including an array substrate.

### BRIEF DESCRIPTION OF THE DRAWINGS

FIG. 1 is a cross-sectional view illustrating a cross-sectional configuration of an array substrate according to one embodiment.

FIG. 2 is a cross-sectional view illustrating a cross-sectional configuration of a first metal film after a multilayer metal film forming process.

FIG. 3 is a cross-sectional view illustrating a cross-sectional configuration after a first line pattern forming process.

FIG. 4 is a cross-sectional view illustrating a cross-sectional configuration after a SOG layer forming process.

FIG. 5 is a cross-sectional view illustrating a cross-sectional configuration during a second line pattern forming process performed after forming a capping layer.

### DETAILED DESCRIPTION

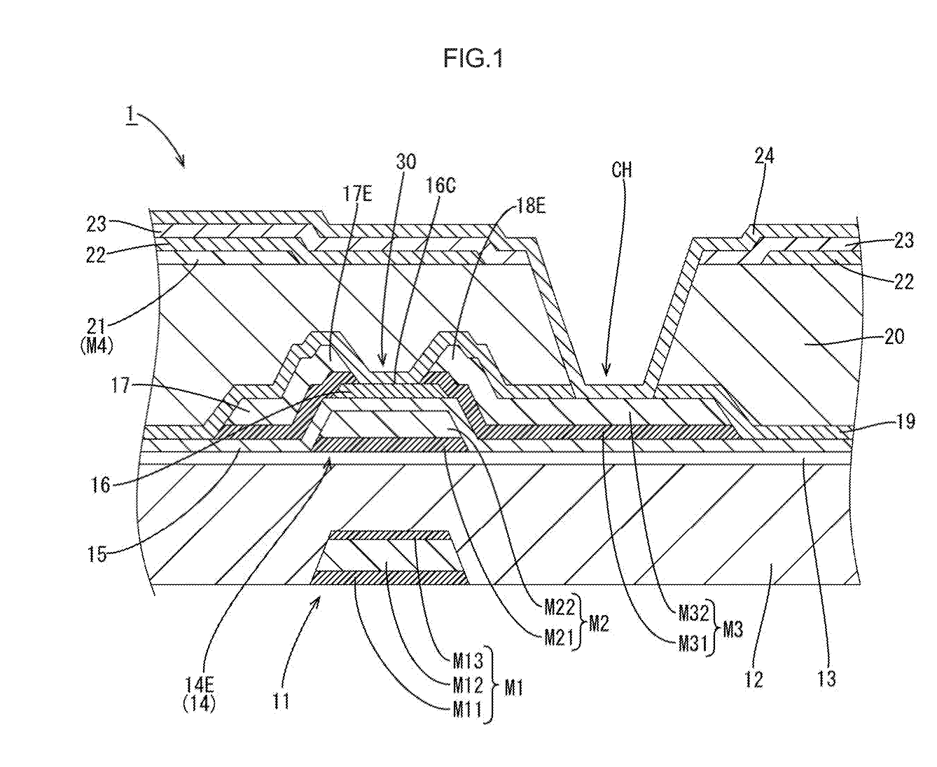

One embodiment according to the technology described herein will be described with reference to FIGS. 1 to 5.

An array substrate 1 will be described. In the following description, an upper side and a lower side in FIG. 1 corresponds with an upper side and a lower side, respectively, and one of the same components is provided with a reference number and a rest of them may not be provided with the reference number.

The array substrate 1 according to this embodiment may be included in various kinds of electronic devices (not illustrated) such as mobile phones (including smartphones), notebook computers (including tablet computers), wearable terminals (including smart watches), handheld terminals (including electronic books and PDAs), portable video game players, and digital photo frames. The array substrate 1 is used in a display panel having a display size in a range between some inches to ten and some inches. The technology described herein is especially suitable for an array substrate used for a display panel in a size that is classified as a small or a small-to-medium and such a display panel is demanded to enhance resolution. However, the technology described herein is not limited to such an array substrate but may be applied to an array substrate included in a display panel having a screen size of dozens of inches or more and being classified as a medium or a large (extra-large).

A display panel including the array substrate 1 according to this embodiment is not illustrated and a liquid crystal panel having a known configuration is used as the display panel. The liquid crystal panel includes the array substrate 1 and a counter substrate that are bonded to be opposite each other having a predetermined cell gap therebetween and liquid crystals are enclosed between the substrates. The counter substrate includes a glass substrate and further includes color filters and counter electrodes on the glass substrate. The color filters include color portions of red (R), green (G), and blue (B) that are arranged in certain arrangement. Alignment films are disposed on an inner side (a liquid crystal layer side) of the array substrate 1 and the counter substrate and polarizing plates are disposed on outer surfaces of the substrates.

A configuration of the array substrate 1 will be described with reference to FIG. 1.

The array substrate 1 is formed from an insulation substrate such as a glass substrate, a silicon substrate, and a heat-resistant plastic substrate, and includes a substantially transparent substrate having high transmissivity, which is not illustrated. In this embodiment, a glass substrate is used as the array substrate 1. As illustrated in FIG. 1, various kinds of layers are stacked in a certain pattern on the glass substrate. The liquid crystal layer and the counter substrate, which are not illustrated, are arranged on the array substrate 1 in FIG. 1 and thus the liquid crystal panel is obtained.

Various kinds of layers are disposed on the inner side (the liquid crystal layer side, the counter substrate side) of the array substrate 1 with the known film deposition technology or the photolithography method.

The array substrate 1 includes thin film transistors (TFTs) 30, which are switching components, and pixel electrodes 24 in a display section and the TFTs 30 and the pixel electrodes 24 are arranged in a matrix. A planar configuration of the array substrate 1 is not illustrated. In a plan view, gate lines (scanning lines, which will be described in detail later) 11, 14 and source lines (signal lines) 17 are arranged to cross each other and routed around the TFTs 33 and the pixel electrodes 24. Namely, each of the TFTs 30 and each of the pixel electrodes 24 are arranged at each intersection of the gate lines 11, 14 and the source lines 17 that are arranged in a grid pattern.

As illustrated in FIG. 1, the TFT 30 includes a gate electrode 14E extending from a second gate line 14 of a double-layer gate line, a channel section 16C formed on a semiconductor film 16, a source electrode 17E extending from a source line 17, and a drain electrode 18E. The source electrode 17E is opposite the drain electrode 18E having the channel section 16C therebetween and the source electrode 17E and the drain electrode 18E are opposite each other on the semiconductor film 16 while having a certain distance therebetween. The source electrode 17E and the drain electrode 18E are electrically connected to the semiconductor film 16 such that electrons move between the source electrode 17E and the drain electrode 18E.

FIG. 1 is a cross-sectional view illustrating a cross-sectional configuration of the array substrate 1.

As illustrated in FIG. 1, on an upper surface (a liquid crystal layer side plate surface) of the glass substrate, the first gate line (a first line) 11 is formed from a first metal film M1 with patterning, and a spin-on glass (SOG) layer 12, which is thick, is disposed to cover the first gate line 11, and an upper surface of the SOG layer 12 is covered with a capping layer 13. On the capping layer 13, a second gate line (a second line) 14 and the gate electrode 14E that are formed from a second metal film M2 are formed with patterning so as to overlap the first gate line 11 in a plan view. A first insulation layer (a gate insulation layer) 15 having an insulation property is disposed to cover the second gate line 14. On the first insulation layer 15, a semiconductor film 16 formed of an oxide semiconductor film, and the source line 17, the source electrode 17E, and the drain electrode 18E that are formed from a third metal film M3 are formed. A second insulation layer 19 having an insulation property is disposed to cover upper surfaces of the semiconductor film 16, the source line 17, the source electrode 17E, and the drain electrode 18E. An organic resin layer 20, which is thick, is disposed on the second insulation layer 19, and a metal line 21 formed from a fourth metal film M4 is disposed on the organic resin layer 20. A common electrode 22 formed of a transparent electrode film and a third insulation layer 23 having an insulation property are disposed in layers to cover the metal line 21. The pixel electrode 24 formed from a transparent electrode film is formed on the third insulation layer 23.

Hereinafter, each of the layers will be described. The first metal film M1, the first gate line 11, the SOG layer 12, and the capping layer 13 will be described after description of other layers.

In this embodiment, the second metal film M2 forming the second gate line 14 and the gate electrode 14E is a double-layer metal film including a lower layer M21 of titanium (Ti) and a copper (Cu) containing layer M22 thereon. The second metal film M2 is formed on the capping layer 13 with the sputtering method. The copper containing layer M22 is subjected to photolithography and wet etching, and the lower layer M21 is subjected to dry etching. A resist is removed and cleaning is performed. Accordingly, the second gate line 14 and the gate electrodes 14E are formed in a predetermined pattern on the capping layer 13.

The first insulation layer 15 is a multilayer film including a lower gate insulation layer formed of silicon nitride (SiNₓ) and an upper gate insulation layer formed of silicon oxide (SiOx, for example, x=2). The first insulation layer 15 is formed with a chemical vapor deposition (CVD) method as appropriate.

The semiconductor film 16 is formed from a film of indium gallium zinc oxide (IGZO) that is a kind of oxide semiconductors. The IGZO film configuring the oxide semiconductor film may be amorphous or crystalline. The crystalline oxide semiconductor may preferably have a crystalline structure of c-axis aligned crystals (CAAC). Such an oxide semiconductor film is used not only for the display TFTs 30 included in the display section of the array substrate 1 displaying an image but also for non-display TFTs (not illustrated) included in a non-display section. The IGZO semiconductor film is formed with a sputtering method and is subjected to photolithography and wet etching, and the resist is removed and cleaned. Accordingly, the semiconductor film 16 having a predetermined pattern is formed on the first insulation layer 15.

The semiconductor film 16 formed of the IGZO semiconductor film has electron mobility higher than that of an amorphous silicon film, for example, 20 to 50 times higher. Therefore, the display area of the TFTs 30 can be easily downsized and an aperture ratio of the display pixel in the display area can be increased.

The third metal film M3 forming the source line 17, the source electrode 17E, and the drain electrode 18E is a double-layer metal film including a lower layer M31 of titanium (Ti) and a copper (Cu) containing layer M32 on the lower layer M31 similar to the configuration of the second metal film M2. The third metal film M3 is formed on the first insulation layer 15 with the sputtering method. The copper containing layer M32 is subjected to photolithography and wet etching, and the lower layer M31 is subjected to dry etching. A resist is removed and cleaning is performed. Accordingly, the source line 17, the source electrode 17E, and the drain electrode 18E are formed in a predetermined pattern on the first insulation layer 15. Then, the channel section 16C of the semiconductor film 16 is exposed between the source electrode 17E and the drain electrode 18E.

The second insulation layer (an inorganic interlayer insulation layer) 19 is a multilayer film including a lower insulation layer formed of silicon nitride (SiN_{g}) and an upper insulation layer formed of silicon oxide (SiOx, for example, x=2). The second insulation layer 19 is formed with a plasma chemical vapor deposition (CVD) method to cover upper surfaces of the source electrode 17E, the drain electrode 18E, and the channel section 16C of the semiconductor film 16 between the source electrode 17E and the drain electrode 18E.

The organic resin layer (an organic insulation layer) 20 is formed of organic resin material such as acrylic resin (e.g., polymethyl methacrylate (PMMA)), epoxy resin, phenol resin that are photosetting or thermosetting. Photosensitive organic resin material is preferable. The organic material is disposed on the second insulation layer 19 with the spin coating method or the slit coating method. After a pattern is formed on the disposed organic material with the photolithography method, the annealing treatment is performed and the organic resin layer 20 having a predetermined pattern is formed. The organic resin layer 20 has a thickness of 1 μm or more and the thickness of the organic resin layer 20 is greater than that of other layers of the inorganic material, which is about 0.2 μm. The thick organic resin layer 20 functions as a flattening layer.

The fourth metal film M4 forming the metal line 21 is formed on the organic resin layer 20. In this embodiment, the fourth metal film M4 may be a metal film of a single layer or may be a multilayer metal film such as the double-layer metal film including a layer of titanium (Ti) and a copper containing layer thereon similar to the second metal film M2 and the third metal film M3. The fourth metal film M4 is formed on the organic resin layer 20 with the sputtering method and is subjected to photolithography and wet etching. A resist is removed and cleaning is performed. Accordingly, the metal line 21 is formed in a predetermined pattern on the organic resin layer 20.

The common electrode 22 is formed from a transparent conductive film such as indium tin oxide (ITO) and zinc oxide (ZnO). The transparent conductive film is formed with the sputtering method. The transparent conductive film is subjected to photolithography and wet etching, and a resist is removed and cleaning is performed. Accordingly the common electrode 22 having a predetermined pattern is formed. The common electrode 22 is formed on the organic resin layer 20 having the metal line 21 with patterning and is formed over a substantially entire area of the display section of the array substrate 1 to cover the pixels. Accordingly, the common electrode 22 is commonly used by the pixels.

The third insulation layer (an inorganic interlayer insulation layer) 23 is formed of silicon nitride (SiNₓ) forming a dense film and is formed with the plasma CVD method. The third insulation layer 23 covers and protects an upper surface of the common electrode 22.

The pixel electrode 24 is formed from the transparent conductive film such as ITO and ZnO similar to the common electrode 22. The transparent conductive film formed of ITO with sputtering is subjected to photolithography and wet etching, and a resist is removed and cleaning is performed so that the pixel electrode 24 is formed. The pixel electrode 24 is arranged in a quadrangular section (the pixel) surrounded by the gate lines 11, 14 and the source lines 17 in a plan view of the array substrate 1. The pixel electrode 24 is mainly formed on the third insulation layer 23.

The second insulation layer 19, the organic resin layer 20, the common electrode 22, the third insulation layer 23, and the pixel electrode 24 are arranged on the array substrate 1 to cover the TFTs 30 (to cover the channel sections 16C of the TFTs 30).

The third insulation layer 23, the common electrode 22, the organic resin layer 20, and the second insulation layer 19 have a contact hole CH therethrough in an appropriate position. As illustrated in FIG. 1, the pixel electrode 24 is connected to the drain electrode 18E through the contact hole CH. The pixel electrode 24 includes a quadrangular body portion covering the pixel section, an overlapping portion overlapping the TFT 30, and a connection portion connected to the drain electrode 18E through the contact hole CH.

The array substrate 1 according to this embodiment includes the first gate line 11, which is formed from the first metal film M1 with patterning, and the SOG layer 12 between the glass substrate and the second metal film M2. Further, the capping layer 13 is formed on the SOG layer 12 to cover the upper surface of the SOG layer 12 and is disposed between the SOG layer 12 and the second line 14.

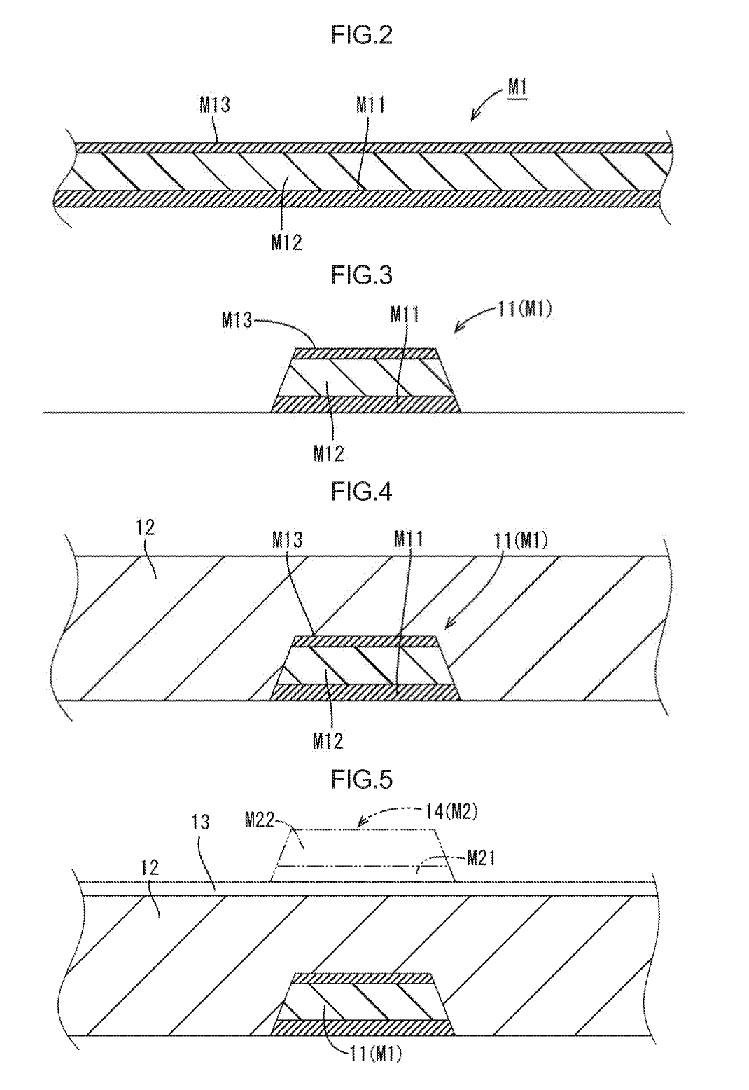

Next, a method of forming the layers will be described with reference to FIGS. 2 to 4.

The first metal film M1 forming the first gate line 11 is a three-layer metal film including a lower layer M11 made of titanium (Ti), a copper (Cu) containing layer M12 on the lower layer M11, and a metal upper layer M13 made of titanium (Ti) on the copper containing layer M12.

As illustrated in FIG. 2, titanium and copper (copper containing layer forming metal) and titanium (metal upper layer forming metal) are deposited on the glass substrate with sputtering sequentially and a three-layer metal film is formed on the glass substrate (a multilayer metal film forming process). The three-layer metal film is not necessarily formed directly on the glass substrate but may be formed on another layer such as an insulation layer formed on the glass substrate. Next, the metal upper layer M13 is subjected to photolithography and wet etching, and the copper containing layer M12 and the lower layer M11 are subjected to dry etching and the resist is removed and cleaning is performed. Accordingly, as illustrated in FIG. 3, the first gate line 11 having a predetermined pattern is formed on the glass substrate (a first line pattern forming process). In this embodiment, as illustrated in FIG. 1, the first gate line 11 has a line width and a film thickness that are substantially same as those of the second gate line 14. The first gate line 11 is electrically connected to the second gate line 14 through a through hole formed in the SOG layer 12, which will be described later.

The SOG layer (an insulation glass layer) 12 is formed from SOG material. The SOG material is not especially limited but may be SOG material having various kinds of chemical structures including organic SOG material and inorganic SOG material. Photosensitive SOG material is preferable to be used to form a pattern thereon easily. Considering the heat resistance property required in the subsequent process, the SOG material that is thermally cured at the end is preferable. The SOG material is disposed on the glass substrate, on which the first gate line 11 is formed, with the spin coating method and a pattern is formed thereon with photolithography and wet etching and thereafter, the patterned SOG material is subjected to the annealing treatment and the thermosetting process. Accordingly, as illustrated in FIG. 4, the SOG layer 12 having a predetermined pattern is formed (a SOG layer forming process). Similar to the organic resin layer 20, the SOG layer 12 is formed such that a thickness thereof is relatively larger than that of other layers. For example, the thickness of the SOG layer 12 is 1 μm or more.

The capping layer 13 is formed of silicon nitride (SiNₓ) or silicon oxide (SiOx, for example, x=2). In this embodiment, the capping layer 13 is formed of silicon nitride providing a dense film structure. Therefore, silicon nitride is especially preferable to cover the SOG layer 12 and restrict discharge of gas from the SOG layer. The capping layer 13 may be formed on the SOG layer 12 with the CVD method.

As illustrated in FIG. 5, after forming the capping layer 13, the second gate line 14 is formed with patterning on the capping layer 13 (disposed on the SOG layer 12) at a position overlapping the pattern of the first gate line 11 in a plan view of the array substrate 1 (a second line pattern forming process). Thus, the array substrate 1 according to this embodiment is produced.

Operations of the liquid crystal panel including the array substrate 1 having the above-described configuration will be simply described.

In the array substrate 1, the body portion and the overlapping portion of the pixel electrode 24 are opposite the common electrode 22 via the third insulation layer 23. The common electrode 22 is supplied with a common potential (a reference potential) by a common line, which is not illustrated. The TFT 30 controls a potential applied to the pixel electrode 24 to generate predetermined potential difference between the pixel electrode 24 and the common electrode 22.

When potential difference appears between the pixel electrode 24 and the common electrode 22, a fringe field (an oblique field) including a component in a direction normal to a plate surface of the array substrate 1 is applied to the liquid crystal layer that is between the array substrate 1 and the counter substrate. The alignment of the liquid crystal molecules in the liquid crystal layer is properly switched by controlling the electric filed to display an image on the display section.

As described before, the array substrate 1 according to this embodiment has a multilayer structure including the SOG layer 12 formed of SOG material, the first gate line (the first line) 11 disposed on a lower side (on an opposite side from the liquid crystal layer) with respect to the SOG layer 12, and the second gate line (the second line) 14 disposed on an upper side (on the liquid crystal layer side) with respect to the SOG layer 12 so as to overlap the first gate line 11 in a plan view of the array substrate 1. The first gate line 11 includes the copper containing layer M12 formed of copper and the metal upper layer M13 formed of titanium. The metal upper layer M13 is disposed on the copper containing layer M12 and between the copper containing layer M12 and the SOG layer 12.

According to the configuration of the above embodiment, the gate line on the array substrate 1 has a double-layer structure including the first gate line 11 and the second gate line 14 overlapping the first gate line 11 in a plan view. According to such a configuration, each of the first gate line 11 and the second gate line 14 can keep effective line thickness and reduce line width without increasing the electric resistance to increase the aperture ratio of the pixels and enhance resolution of the displayed image.

In this embodiment, the first gate line 11 and the second gate line 14 have substantially same line width and substantially same line thickness. According to such a configuration, the line width and the line thickness of the gate lines can be maintained within a certain range and increase of the electric resistance is effectively restricted.

According to the configuration of this embodiment, the SOG layer 12 formed of SOG material is disposed as an insulation layer between the first gate line 11 and the second gate line 14 included in the double-layer structure. The SOG layer 12 is superior in the heat-resistance property. Therefore, the insulation layer is less likely to be deteriorated or modified by the high temperature annealing treatment that is to be performed in the process of producing a liquid crystal panel after forming the SOG layer 12. A highly reliable liquid crystal panel can be obtained with using the array substrate 1. As is in this embodiment, a pattern can be formed on the photosensitive SOG material in the photolithography process. Therefore, the number of processes in producing the array substrate 1 is less likely to be increased.

In the array substrate 1 including the double-layer gate line, if the first gate line 11, which is included on the lower side with respect to the SOG layer 12, is formed from a known multilayer metal film including two layer structure, copper included in the exposed upper layer is contacted with the SOG layer 12. In the array substrate having such a configuration, copper included in the first gate line 11 is oxidized by the heating process performed for curing the SOG layer 12. To restrict the oxidization of copper and keep low electric resistivity, it is necessary to form a metal capping layer formed of silicon nitride to cover the first gate line after forming the first gate line. This increases the number of processes in producing an array substrate.

According to the configuration of this embodiment, the metal upper layer M13 formed of titanium is disposed between the copper containing layer M12 of the first gate line 11 and the SOG layer 12 that may oxidize the copper included in the copper containing layer M12. Therefore, oxidization of the copper included in the copper containing layer M12 is restricted without forming the metal capping layer and the electric resistivity of the line can be kept low.

According to the configuration of this embodiment, the metal upper layer M13 is formed of titanium. Namely, the metal upper layer M13 is formed of one selected from a metal group consisting of titanium, an aluminum alloy, a copper alloy, a tungsten alloy, and a tantalum alloy. With using such a metal for the metal upper layer M13, the metal upper layer M13 that is dense can be formed on the upper surface of the copper containing layer M12. Furthermore, with using such a metal, the copper containing layer M12 and the metal upper layer M13 are formed with a simple process of disposing sequentially the metal containing copper and the metal upper layer with sputtering.

The array substrate 1 according to this embodiment includes the capping layer 13 that is disposed on the SOG layer 12 and between the SOG layer 12 and the first gate line 11.

In the high temperature annealing treatment that is performed in the liquid crystal panel forming process after forming the gate lines 11, 14 and the SOG layer 12, gas may be discharged from the SOG layer 12. According to the configuration of this embodiment including the capping layer 13 covering the SOG layer 12, gas is less likely to be discharged from the SOG layer 12 and problems relating the discharge of gas are less likely to be caused. As is in this embodiment, the capping layer 13 that is formed of silicon nitride is effective because a dense layer can be formed. Adherence of the SOG layer 12 and the second gate line 14 can be improved by disposing the capping layer 13 therebetween.

The array substrate 1 of this embodiment is produced with a following method. The method includes a multilayer metal film forming process, a first line pattern forming process, a SOG layer forming process, and a second line pattern forming process. In the multilayer metal film forming process, a multilayer metal film is formed and the multilayer metal film includes the copper containing layer M12 including copper and the metal upper layer M13 disposed on the copper containing layer M12 and formed of one selected from a group consisting of titanium, an aluminum alloy, a copper alloy, a tungsten alloy, and a tantalum alloy. In the first line pattern forming process, the multilayer metal film is subjected to etching to form the first gate line 11 with patterning. In the SOG layer forming process, the SOG layer 12 formed of SOG material is formed on the first gate line 11. In the second line pattern forming process, the second line 14 is formed with patterning on the SOG layer 12.

The multilayer metal film is formed by disposing metal including copper and metal upper layer forming metal sequentially with sputtering. According to the configuration of this embodiment, the first line pattern is formed with etching after the multilayer metal film including the metal upper layer M13 in a most upper layer is formed. Accordingly, the contact area in which the copper containing layer M12 and the SOG layer 12 are directly in contact with each other is reduced and a metal capping layer is not required to be formed. With the configuration including the SOG layer 12 formed of photosensitive SOG material, the pattern can be formed with the photolithography method. Therefore, the number of processes in producing the array substrate 1 is less likely to be increased. As a result, oxidization of the copper containing layer M12 included in the first gate line 11 is less likely to be caused in the array substrate 1 and the highly reliable array substrate 1 can be obtained with a simple process.

The array substrate 1 of this embodiment is used in a liquid crystal panel. Accordingly, a liquid crystal panel that can display an image with high resolution can be obtained.

### Other Embodiments

The technology disclosed herein is not limited to the embodiment, which have been described using the foregoing descriptions and the drawings. For example, embodiments described below are also included in the technical scope.

(1) In the above embodiment, the first gate line (the first line) 11 and the second gate line (the second line) 14 have the substantially same line width and the substantially same line thickness. However, it is not limited thereto. For example, the gate lines may have the substantially same line width and the first gate line 11 may have a line thickness greater than that of the second gate line 14. In such a configuration, the line thickness of the second gate line 14 may be reduced. Accordingly, disconnection is less likely to be caused in the various kinds of lines connected to the second gate line 14 and the effective current flow amount can be kept.

(2) In the above embodiment, the first metal film M1 is formed from the three-layer metal film including the metal upper layer formed of titanium, the copper containing layer formed of copper, and the lower layer formed of titanium. However, it is not limited thereto. For example, the first metal film M1 may be formed from a double-layer metal film including a metal upper layer formed of an aluminum alloy and a copper containing layer formed of a copper alloy or may be formed from multilayer metal film including four layers or more. In the above embodiment, the second metal film M2 and the third metal film M3 are formed from the double-layer metal film. However, each of the films M2, M3 may be formed from a single layer metal film.

(3) In the above embodiment, the array substrate 1 includes the TFTs 30 as switching components of the liquid crystal display panel. However, array substrates that include switching components other than TFTs (e.g., thin film diodes (TFDs)) may be included in the scope of the present technology. Furthermore, array substrates used in black-and-white liquid crystal display panels are also included in the scope of the present technology.

(4) In the above embodiment, the first insulation layer 15, the second insulation layer 19, and the third insulation layer 23 are formed of silicon oxide (SiOx) and/or silicon nitride (SiNx). However, it is not limited thereto. For example, other inorganic material such as silicon nitride/oxide (SiNxOy, x>y), silicon oxide/nitride (SiOxNy, x>y) may be used for the insulation layers.

(5) In the above embodiment, the transparent inorganic conductive film such as ITO is used as the material for the pixel electrode. However, in an array substrate used in a reflection type liquid crystal display device, a conductive film formed of titanium, tungsten, nickel, gold, platinum, silver, aluminum, magnesium, calcium, lithium, and an alloy thereof.

(6) The above embodiment includes the array substrate 1 used in a liquid crystal panel of a lateral electric field type that includes a fringe filed switching (FFS) mode in which an electric field is applied to the liquid crystal molecules in a direction parallel to a substrate surface (a lateral direction) as an operation mode. Therefore, a pair of electrodes (the pixel electrode 24 and the common electrode 22) is formed on the array substrate 1. However, the present technology is not limited to such a configuration. An array substrate having no common electrode and used in a display panel that includes an in-plane switching (IPS) mode and a vertical alignment (VA) mode is also included in the scope of the present technology.

(7) The present technology is applied to the array substrate of the liquid crystal panel and may be also applied to an array substrate included in a plasma display panel, an organic EL panel, and an inorganic EL panel. Accordingly, various types of display panels that can display an image with high resolution are obtained.

1. An array substrate comprising:
a spin-on glass layer formed of spin-on glass material;
a first line disposed on a lower side with respect to the spin-on glass layer, the first line including a copper containing layer formed of copper or a copper alloy and a metal upper layer formed of one selected from a group consisting of titanium, an aluminum alloy, a copper alloy, a tungsten alloy, and a tantalum alloy, and the metal upper layer disposed on the copper containing layer and disposed between the copper containing layer and the spin-on glass layer; and
a second line disposed on an upper side with respect to the spin-on glass layer and overlapping the first line in a plan view.

2. The array substrate according to claim 1, further comprising a capping layer disposed on the spin-on glass layer and disposed between the spin-on glass layer and the second line.

3. A method of producing an array substrate comprising:
a multilayer metal film forming process of forming a multilayer metal film including a copper containing layer formed of copper or a copper alloy and a metal upper layer formed of one selected from a group consisting of titanium, an aluminum alloy, a copper alloy, a tungsten alloy, and a tantalum alloy, and the metal upper layer disposed on the copper containing layer;
a first line pattern forming process of forming a first line pattern on the multilayer metal film with etching;
a spin-on glass layer forming process of forming a spin-on glass layer formed of spin-on glass material on the first line pattern; and
a second line pattern forming process of forming a second line pattern so as to overlap the first line pattern in a plan view and be disposed on an upper side with respect to the spin-on glass layer.

4. A display panel comprising:
the array substrate according to claim 1.
